(19) United States
(12) Patent Application Publication
(10) Pub. No.: US 2016/0215381 A1
(43) Pub. Date: Jul. 28, 2016

(54) METHOD OF GROWING ALUMINUM OXIDE ONTO SUBSTRATES BY USE OF AN ALUMINUM SOURCE IN AN ENVIRONMENT CONTAINING PARTIAL PRESSURE OF OXYGEN TO CREATE TRANSPARENT, SCRATCH-RESISTANT WINDOWS

(71) Applicant: Rubicon Technology, Inc., Bensenville, IL (US)

(72) Inventors: Jonathan Benjamin Levine, Chicago, IL (US); John P. Ciraldo, Elgin, IL (US)

(21) Appl. No.: 15/085,075

(22) Filed: Mar. 30, 2016

Related U.S. Application Data
(62) Division of application No. 14/101,957, filed on Dec. 10, 2013.
(60) Provisional application No. 61/790,786, filed on Mar. 15, 2013.

(51) Int. Cl. C23C 14/00; C23C 14/34; C23C 14/08

(52) U.S. Cl. CPC C23C 14/0036; C23C 14/081; C23C 14/3485; C23C 14/3457

(57) ABSTRACT

A system and process for inter alia coating a substrate such as glass substrate with a layer of aluminum oxide to create a scratch-resistant and shatter-resistant matrix comprised of a thin scratch-resistant aluminum oxide film deposited on one or more sides of a transparent and shatter-resistant substrate for use in consumer and mobile devices such as watch crystals, cell phones, tablet computers, personal computers and the like. The system and process may include a sputtering technique. The system and process may produce a thin window that has a thickness of about 2 mm or less, and the matrix (i.e., the combination of the aluminum oxide film and transparent substrate) may have a shatter resistance with a Young's Modulus value that is less than that of sapphire, i.e., less than about 350 gigapascals (GPa). The thin window has superior shatter-resistant characteristics.

### CROSS-REFERENCE TO RELATED APPLICATIONS

This patent application is a divisional patent application of U.S. patent application Ser. No. 14/101,957, filed Dec. 10, 2013, entitled, “METHOD OF GROWING ALUMINUM OXIDE ONTO SUBSTRATES BY USE OF AN ALUMINUM SOURCE IN AN ENVIRONMENT CONTAINING PARTIAL PRESSURE OF OXYGEN TO CREATE TRANSPARENT, SCRATCH-RESISTANT WINDOWS,” and naming Jonathan Levine and John P. Ciraldo as inventors, which claims benefit and priority to U.S. Provisional Patent Application No. 61/790,786 filed on Mar. 15, 2013. The disclosures of both aforementioned patents are incorporated herein, in their entireties, by references.

### BACKGROUND OF THE INVENTION

1.0 Field of the Disclosure

The present disclosure relates to a system, a method, and a device for inter alia coating a material (such as, e.g., a substrate) with a layer of aluminum oxide to provide a transparent, scratch-resistant surface.

2.0 Related Art

There are many applications for use of glass including applications in, e.g., the electronics area. Several mobile devices such as, e.g., cell phones and computers may employ glass screens that may be configured as a touch screen. These glass screens can be prone to breakage or scratching. Some mobile devices use hardened glass such as ion-exchange glass to reduce surface scratching or the likelihood of cracking.

However, an even harder and more scratch resistant surface would be an improvement over the currently available materials. A harder surface over what is currently known and available would reduce the likelihood even more of scratching and cracking. Reducing scratching and cracking tendencies would provide longer life products. Moreover, a reduction in the incidents of accelerated loss of useful life of various products utilizing glass-based displays would be advantageous; especially those products that are handled frequently by users and prone to accidental dropping.

Currently, there are no known products employing film aluminum oxide on transparent substrates, such as, e.g., glass. A method for the Chemical Vapor Deposition growth aluminum oxide has been demonstrated but is, like full sapphire windows, far too cost prohibitive and is a fundamentally different process compared to the invention disclosed here. Ion exchange glass is a hardened glass that is used in many mobile devices to reduce surface scratches and the likelihood of cracking the screen. However, even this product may be prone to breaking and scratching.

The following patent documents provide informative disclosures: WO 87/02713; U.S. Pat. No. 5,350,607; U.S. Pat. No. 5,693,417; U.S. Pat. No. 5,698,314; and U.S. Pat. No. 5,855,950.

Xinhui Mao et al., in their article titled “Deposition of Aluminum Oxide Films by Pulsed Reactive Sputtering,” J. Mater. Sci. Technol., Vol. 19, No. 4, 2003, describe a pulsed reactive sputtering process that may be used to deposit some compound films, which are not easily deposited by traditional direct current (D.C.) reactive sputtering.

P. Jin et al., in their article “Localized epitaxial growth of α-Al₂O₃ thin films on Cr₂O₃ template by sputter deposition at low substrate temperature,” Applied Physics Letters, Vol. 82, No. 7, Feb. 17, 2003, describe low-temperature growth of α-Al₂O₃ films by sputtering.

### SUMMARY OF THE DISCLOSURE

According to one non-limiting example of the disclosure, a system, a method, and a device are provided to inter alia coat a material (such as, e.g., a substrate) with a layer of aluminum oxide to provide a transparent, scratch resistant surface.

In one aspect, a system for creating an aluminum oxide surface on a substrate is provided that includes a chamber to create a partial pressure of oxygen, a device to hold or secure a transparent or translucent substrate within the chamber and a device to create aluminum atoms and/or aluminum oxide molecules in the chamber to interact with the substrate to create a matrix comprising an aluminum oxide film coating a shatter-resistant transparent or translucent substrate.

In one aspect, a process for creating an aluminum oxide enhanced substrate is provided that includes the steps of exposing a transparent or translucent shatter-resistant substrate to a deposition beam comprising energized aluminum atoms and aluminum oxide molecules to create a matrix comprising a scratch-resistant aluminum oxide film adhered to the surface of the transparent or translucent shatter-resistant substrate, and stopping the exposing based on a predetermined parameter producing a hardened transparent or translucent substrate for resisting breakage or scratching.

In one aspect, a substrate comprising a transparent or translucent shatter-resistant substrate and an aluminum oxide film deposited thereon, wherein the combination of the transparent or translucent shatter-resistant substrate and the deposited aluminum oxide film create a matrix resulting in a transparent shatter-resistant window resistant to breakage or scratching. The transparent or translucent shatter-resistant substrate may comprise one of: a boron silicate glass, an aluminum-silicate glass, an ion-exchange glass, quartz, yttria-stabilized zirconia (YSZ) and a transparent plastic. The resulting window may have a thickness of about 2 mm, or less, and the window has a shatter resistance with a Young's Modulus value that is less than that of sapphire, being less than about 350 gigapascals (GPa). In one aspect, the deposited aluminum oxide film may have thickness less than about 1% of a thickness of the transparent or translucent shatter-resistant substrate. In one aspect, the deposited aluminum oxide film may have a thickness between about 10 nm and 5 microns.

Additional features, advantages, and examples of the disclosure may be set forth or apparent from consideration of the detailed description, drawings and attachment. Moreover, it is to be understood that the foregoing summary of the disclosure and the following detailed description and drawings are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate embodiments of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a block diagram of an example of a system for coating a material with a layer of aluminum oxide, the system configured according to principles of the disclosure;

FIG. 2 is a block diagram of an example of a system for coating a material with a layer of aluminum oxide, the system configured according to principles of the disclosure;

FIG. 3 is a flow diagram of an example process for creating an aluminum oxide enhanced substrate, the process performed according to principles of the disclosure.

The present disclosure is further described in the detailed description that follows.

### DETAILED DESCRIPTION OF THE DISCLOSURE

The disclosure and the various features and advantageous details thereof are explained more fully with reference to the non-limiting embodiments and examples that are described and/or illustrated in the accompanying drawings and detailed in the following description. It should be noted that the features illustrated in the drawings are not necessarily drawn to scale, and features of one embodiment may be employed with other embodiments as the skilled artisan would recognize, even if not explicitly stated herein. Descriptions of well-known components and processing techniques may be omitted so as to not unnecessarily obscure the embodiments of the disclosure. The examples used herein are intended merely to facilitate an understanding of ways in which the disclosure may be practiced and to further enable those of skill in the art to practice the embodiments of the disclosure. Accordingly, the examples and embodiments herein should not be construed as limiting the scope of the disclosure. Moreover, it is noted that like reference numerals represent similar parts throughout the several views of the drawings.

The terms “including”, “comprising” and variations thereof, as used in this disclosure, mean “including, but not limited to”, unless expressly specified otherwise.

The terms “a”, “an”, and “the”, as used in this disclosure, mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously. Moreover, not all steps may be required for every implantation.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

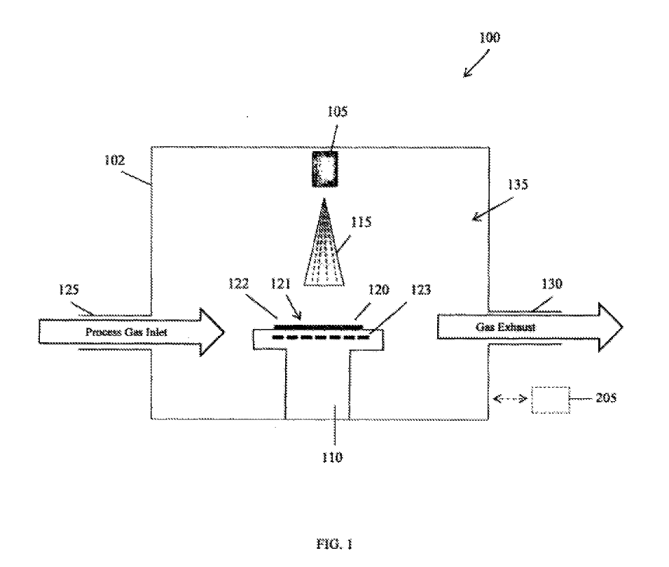

FIG. 1 is a block diagram of an example of a system 100 for coating a material (such as, e.g., a substrate 120 such as glass) with a layer 121 of aluminum oxide, according to the principles of the disclosure. The system 100 may be employed to produce a very hard and superior scratch-resistant surface on glass, or other substrates. For example, coating an ion-exchange glass or boron silicate glass with aluminum oxide, which might be sapphire, makes a superior product for use in applications where a hard, scratch-resistant surface is beneficial, such as glass windows useable, e.g., in electronic devices or scientific instruments, and the like.

As shown in FIG. 1, system 100 may include an evacuation chamber 102 with partial pressure of process gas 135 created therewithin, including molecular or atomic oxygen. The device 100 may further include an aluminum source 105, a stage 110, a process gas inlet 125, and a gas exhaust 130. The stage 110 may be configured to be heated (or cooled). The stage 110 may be configured to move in any one or more dimensions of 3-D space, including configured to be rotatable, movable in a x-axis, movable in a y-axis and/or movable in a z-axis.

The substrate 120 may be a planar material or a non-planar material. The substrate 120 may be transparent or translucent. The substrate material 120 (such as, e.g., glass, or the like) may be placed on the stage 110. The substrate material 120 may have one or more surfaces that may be subject to treatment. The substrate may be a boron silicate glass. In some applications, the substrate 120 may be embodied in multiple dimensions, e.g., to include surfaces oriented in three dimensions that may be coated by the coating process. The aluminum source 105 is configured to produce a controlled deposition beam 115 comprising aluminum atoms and/or aluminum oxide molecules. The deposition beam 115 may be a cloud-like beam. The aluminum source 105 may comprise a sputtering mechanism. The aluminum source 105 may include a device to heat aluminum. Traditional sputtering may be employed. The targeting of the aluminum atoms and/or aluminum oxide molecules may include adjusting the location of the aluminum source 105 and/or adjusting the orientation of the stage 110. Adjusting an orientation or position of the substrate 120 relative to the aluminum ions 115 may adjust an exposure amount of the aluminum ions to the substrate 120. This adjusting may also permit coating of the aluminum oxide to particular or additional sections of the substrate 120.

The system 100 may be used to coat a layer of aluminum oxide (which may be sapphire) on the target substrate material 120 (e.g., a substrate, such as glass) to provide a matrix 121 layer comprising a transparent, scratch resistant surface 122. The resultant scratch resistant surface 122 may comprise a window that may have applications for many consumer products including, e.g., a watch crystal, a camera lens, and e.g., touch screens for use in e.g., mobile phones, tablet computers and laptop computers, where maintaining a scratch-free or break-resistant surface may be of primary importance. A thin window that may be created may have a thickness of about 2 mm or less. The thin window is configured and characterized as having a shatter resistance with a Young's Modulus value that is less than sapphire, which may be less than about 350 gigapascals (GPa). Moreover, it should be understood that, in the case that there are different values for the Young's Modulus based on a testing method or region of material tested (e.g., ion-exchange glass, which may have different values for the surface and the bulk), that the lowest value is the applicable value.

A benefit provided by the resultant matrix 121 at surface 122 of this disclosure includes superior mechanical performance, such as, e.g., improved scratch resistance, greater resistance to cracking compared to currently used materials such as traditional untreated glass, plastic, and the like. Additionally, by using aluminum oxide coated on glass rather than an entire sapphire window (i.e., a window comprising all sapphire), the cost may be reduced substantially, making the product available for widespread consumer usage. Moreover, the use of aluminum oxide films, as opposed to full sapphire windows, offers additional cost savings by eliminating the need to cut, grind, and/or polish sapphire, which may be difficult and costly.

According to an aspect of the disclosure, a substrate 120, such as, e.g., glass, quartz, or the like, may be placed onto a stage 110 which may be heated within an evacuated chamber 102. Process gases are permitted to flow into the evacuation chamber 102 such that a controlled partial pressure is achieved. This gas may contain oxygen either in atomic or molecular form, and may also contain inert gases such as argon. Upon achieving the desired partial pressure, a deposition beam comprising energized aluminum atoms and/or aluminum oxide molecules 115 may be introduced such that the substrate 120 is exposed to an aluminum oxide deposition beam 115. Being exposed to oxygen within the evacuation chamber 102, the aluminum atoms may form aluminum oxide (Al₂O₃) molecules, which adhere to the substrate surface 122, the combination forming a matrix 121. The combination that forms the matrix 121 provides exceptional useful qualities including, e.g., improved scratch resistance and greater resistance to cracking.

If the deposition beam 115 is not sufficiently large enough to homogeneously cover the substrate surface 122, the substrate 120 itself may be moved in the deposition beam, such as, e.g., through movement of the stage 110 which may be controlled to move up, down, left, right, and/or to rotate, to allow an even coating. In some implementations, the aluminum source 105 may be moved. Moreover, the substrate 120 may be heated by a heating device 123 sufficiently to allow mobility of ablated particles on the surface 122 of the substrate 120, allowing for improved quality of the coating agent. The matrix 121 formed at the surface 122 of the substrate chemically and/or mechanically adheres to the substrate surface 122 which creates a bond sufficiently strong enough to substantially prevent delamination of the aluminum oxide (Al₂O₃) with the substrate 120, creating a hard and strong surface 120 that is highly resistant to breaking and/or scratching.

The growth rate of the aluminum oxide (Al₂O₃) layer forming matrix 121 at the surface 122 may be tunable. The growth rate of the aluminum oxide (Al₂O₃) layer forming matrix layer 121 may be enhanced by reducing the distance between the aluminum source 105 and the substrate 120. The growth rate may be further enhanced by optimizing sputter power, as well as ambient gas pressure and composition.

The substrate 120 may be exposed to the aluminum oxide deposition beam, and the exposure stopped based on a predetermined parameter such as, e.g., a predetermined time period and/or a predetermined depth of layering of aluminum oxide on the substrate being achieved. The predetermined parameter may include a predetermined amount of aluminum oxide deposited such that the amount is sufficient to achieve a desired amount of scratch resistance, but not thick enough to affect the shatter resistance of the substrate. In some applications, the amount of aluminum oxide deposited may have a thickness less than about 1% of the thickness of the substrate. In some applications the amount of aluminum oxide deposited may range between about 10 nm and 5 microns. In some applications, the deposited amount of aluminum oxide may be less than about 10 microns thick.

To generate source atoms of aluminum, the use of a radio frequency (RF) or pulsed direct current (DC) sputtered power source may be employed in order to counteract charge accumulation that result from the dielectric nature of aluminum oxide. Coated layers several nanometers to several hundred microns thick can be achieved depending on the process parameters and duration.

Process duration can be several minutes to several hours. By controlling the aluminum atom and/or aluminum oxide flux and oxygen partial pressure, the properties of the coated film (i.e., the aluminum oxide) can be tailored to maximize the films scratch resistance and mechanical adhesion of the grown film. The film on the substrate results in a strong matrix that is very difficult to separate. The film is conformal to the surface of the substrate. This conformance characteristic may be useful and advantageous to coat irregular surfaces, non-planar surfaces or surfaces with deformities. Moreover, this conformance characteristic may result in a superior bond over, for example, a laminate technique, which typically does not adhere well to irregular surfaces, non-planar surfaces, or surfaces with certain deformities.

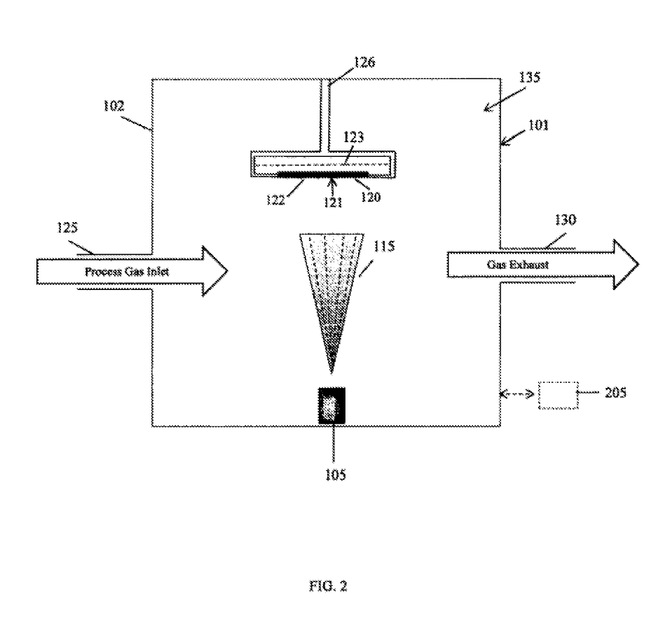

FIG. 2 is a block diagram of an example of a system 101, configured according to principles of the disclosure. The system 101 is similar to the system of FIG. 1 and works principally the same way, except that the substrate 120 may be oriented differently, which in this example, is oriented above the aluminum source 105. The deposition beam 115 may be controlled to direct the atoms upwardly towards the suspended substrate 120. Adjusting an orientation or position of the substrate 120 relative to the aluminum atoms 115 may adjust an exposure amount of the aluminum atoms to the substrate 120. This may also permit coating of the aluminum oxide to particular or additional sections of the substrate 120. Traditional sputtering may be employed.

The system of FIG. 2 may also generally illustrate that the relationship of the substrate 120 and the aluminum source 105 might be in any practical orientation. An alternate orientation may include a lateral orientation wherein the substrate 120 and the aluminum source may be laterally positioned relative to each other.

In FIG. 2, the substrate 120 may be held in position by a securing mechanism 126. The securing mechanism 126 may include an ability to move in any axis. Moreover, the securing mechanism 126 may include a heater 123 configured to heat the substrate 120.

The substrate 120 may be exposed to the aluminum and aluminum oxide deposition beam, and the exposure stopped based on a predetermined parameter such as, e.g., a predetermined time period and/or a predetermined depth of layering of aluminum oxide on the substrate being achieved.

In one aspect, a thin window that may be created by the systems of FIG. 1 and FIG. 2 may have a thickness of about 2 mm or less. The thin window may be configured and characterized as having a shatter resistance with a Young's Modulus value that is less than that of sapphire, i.e., less than about 350 gigapascals (GPa). Moreover, it should be understood that, in the case that there are different values for the Young's Modulus based on a testing method or region of material tested (e.g., ion-exchange glass, which may have different values for the surface and the bulk), that the lowest value is the applicable value.

In some implementations, the systems 100 and 101 may include a computer 205 to control the operations of the various components of the systems 100 and 101. For example, the computer 205 may control the heater 123 for heating of the aluminum source. The computer may also control the motion of the stage 110 or the securing mechanism 126 and may control the partial pressures of the evacuation chamber 102. The computer 205 may also control the tuning of the gap between the aluminum source and the substrate 120. The computer 205 may control the amount of exposure duration of the deposition beam 115 with the substrate 120, perhaps based on, e.g., a predetermined parameter(s) such as time, or based on a depth of the aluminum oxide formed on the substrate 120, or amount/level of pressure employed of oxygen, or any combination therefore. The gas inlet 125 and gas outlet may include valves (not shown) for controlling the movement of the gases through the systems 100 and 200. The valves may be controlled by computer 205. The computer 205 may include a database for storage of process control parameters and programming.

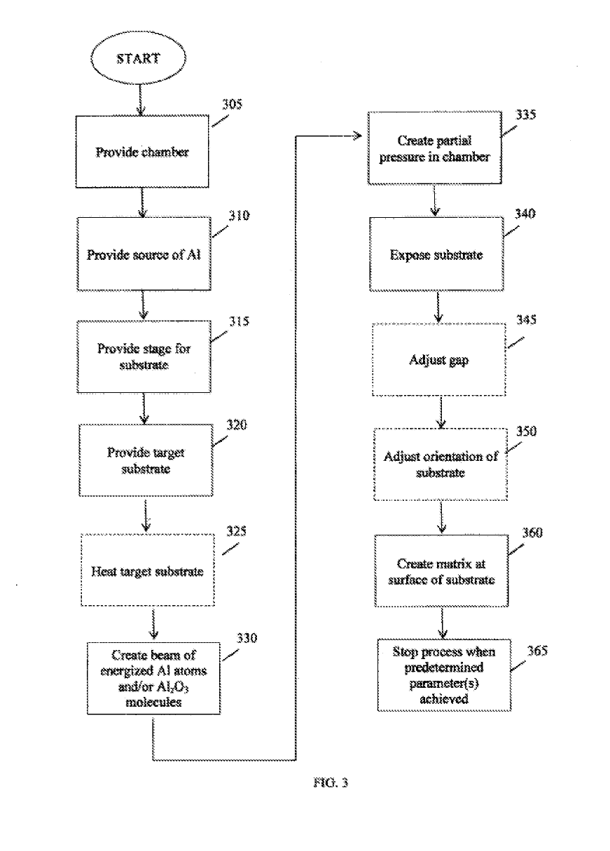

FIG. 3 is a flow diagram of an example process for creating an aluminum oxide enhanced substrate, the process performed according to principles of the disclosure. The process of FIG. 3 may include a traditional type of sputtering. The process of FIG. 3 may be used in conjunction with the systems 100 and 101. At step 305, a chamber, e.g., evacuation chamber 102, may be provided that is configured to permit a partial pressure to be created therein, and configured to permit a target substrate 120 such as, e.g., glass or boron silicate glass to be coated. At step 310, a source of aluminum 105 may be provided that enables energized aluminum atoms 115 to be generated in the evacuation chamber 102. This may comprise a sputtering technique. At step 315, a support securing mechanism 126 or stage such as, e.g., stage 110, may be configured within the chamber 102, depending on the type of system employed. The stage 110 and/or securing mechanism 126 may be configured to be rotatable. The stage 110 and securing mechanism 126 may be configured to be moved in a x-axis, a y-axis and a z-axis.

At step 320, a target substrate 120 having one or more surfaces such as, e.g., glass, borosilicate glass, aluminum-silicate glass, plastic, or yttria-stabilized zirconia (YSZ), may be placed on the stage 110, or alternatively by the securing mechanism 126. At optional step 325, the target substrate 120 may be heated. At step 330, a deposition beam 115 may be created which comprises aluminum atoms and/or aluminum oxide molecules. At step 335, a partial pressure may be created within the chamber. This may be achieved by permitting oxygen to flow into the evacuation chamber 102. At step 340, the substrate 120 is exposed to the deposition beam 115 of aluminum atoms and/or aluminum oxide molecules to coat the substrate 120. The exposure may be based on one or more predetermined parameter(s) such as, e.g., a depth of the aluminum oxide being formed on the target substrate surface(s), time duration, or a pressure level of the oxygen in the evacuation chamber 102, or combinations thereof. The aluminum atoms and aluminum oxide molecules may form the deposition beam 115 directed towards the target substrate 120.

At optional step 345, a gap or distance between the aluminum source 105 and the target substrate 120 may be adjusted to increase or decrease a rate of coating the target substrate 120. At optional step 350, the target substrate 120 may be re-positioned by adjusting the orientation of the stage 110, or adjusting the orientation of the securing mechanism 126. The stage 110 and/or securing mechanism 126 may be rotated or moved in any axis. At step 360, a matrix 121 may be created at one or more surfaces of the target substrate 120 as the aluminum atoms and aluminum oxide molecules coat and bond with the one or more surfaces of the substrate 120. At step 365, the process may be terminated when one or more predetermined parameter(s) are achieved such as time, or based on a depth/thickness of the aluminum oxide formed on the substrate 120, or amount/level of pressure employed of oxygen, or any combination therefore. Moreover, a user may stop the process at any time.

The process of FIG. 3 may produce a thin window that is lightweight, has superior resistance to breakability and has a thickness of about 2 mm or less. The thin window is configured and characterized as having a shatter resistance with a Young's Modulus value that is less than that of sapphire, i.e., less than about 350 gigapascals (GPa). Moreover, it should be understood that, in the case that there are different values for the Young's Modulus based on a testing method or region of material tested (e.g., ion exchange glass which may have different values for the surface and the bulk), that the lowest value is the applicable value. The thin window produced by the process of FIG. 3 may be used to produce transparent thin windows including, e.g., watch crystals, lenses, touch screens in, e.g., mobile phones, tablet computers, and laptop computers, where maintaining a scratch-free or break-resistant surface may be of primary importance. The process may be used on a translucent type of substrate materials also.

The steps of FIG. 3 may be performed by or controlled by a computer, e.g., computer 205 that is configured with software programming to perform the respective steps. The computer 205 may be configured to accept user inputs to permit manual operations of the various steps.

While the disclosure has been described in terms of examples, those skilled in the art will recognize that the disclosure can be practiced with modifications in the spirit and scope of the appended claims. These examples are merely illustrative and are not meant to be an exhaustive list of all possible designs, embodiments, applications or modifications of the disclosure.

What is claimed:

1. A method of forming a window, the method comprising:
providing a substrate having an outer surface;
positioning an aluminum source in an environment, the aluminum source having aluminum atoms; and
reacting, using a sputtering process, at least some of the aluminum atoms from the aluminum source with oxygen in the environment to form aluminum oxide to reactively physically vapor deposit the aluminum oxide on the outer surface of the substrate.

2. The method as defined by claim 1 wherein reacting comprises forming a deposition beam of the aluminum atoms.

3. The method as defined by claim 2 further comprising adjusting an orientation or position of the substrate relative to the deposition beam.

4. The method as defined by claim 1 wherein the aluminum oxide forms an aluminum oxide film on the outer surface of the substrate.

5. The method as defined by claim 1 wherein the substrate comprises ion exchange glass.

6. The method as defined by claim 5 wherein the substrate comprises at least one of soda-lime glass, borosilicate glass, aluminosilicate glass, and yttria-stabilized zirconia.

7. The method as defined by claim 1 wherein the aluminum source is substantially pure aluminum.

8. The method as defined by claim 1 wherein the substrate is substantially transparent or substantially translucent, the aluminum oxide on the outer surface of the substrate forming a substantially transparent or substantially translucent aluminum oxide film.

9. The method as defined by claim 1 further comprising heating the substrate.

10. The method as defined by claim 1 wherein the aluminum oxide comprises sapphire.

11. The method as defined by claim 1 wherein the aluminum oxide on the outer surface forms a conformal film conforming to the substrate.

12. The method as defined by claim 1 wherein the substrate and deposited aluminum oxide on the outer surface of the substrate have a thickness of 2 mm or less.

13. The method as defined by claim 1 wherein reacting comprises using a radio frequency or pulsed direct current power source.

14. A method of forming a window, the method comprising:
providing a substrate having an outer surface, the substrate comprising ion exchange glass;
positioning substantially pure aluminum in an environment, the aluminum having aluminum atoms;
permitting oxygen to be within the environment; and
physically vapor depositing aluminum oxide on the outer surface of the substrate, physically vapor depositing comprising reacting, using a sputtering process, at least some of the aluminum atoms from the substantially pure aluminum with the oxygen in the environment to form the aluminum oxide.

15. The method as defined by claim 14 wherein reacting comprises forming a deposition beam of the aluminum atoms, the aluminum atoms in the beam reacting with the oxygen.

16. The method as defined by claim 14 wherein the aluminum oxide on the outer surface forms a conformal film conforming to the substrate.

17. The method as defined by claim 14 wherein the substrate comprises at least one of soda-lime glass, borosilicate glass, aluminosilicate glass, and yttria-stabilized zirconia.

18. The method as defined by claim 14 wherein the aluminum is substantially pure aluminum.

19. The method as defined by claim 14 wherein the substrate is substantially transparent or substantially translucent, the aluminum oxide on the outer surface of the substrate forming a substantially transparent or substantially translucent aluminum oxide film.

20. The method as defined by claim 14 wherein reacting comprises using a radio frequency or pulsed direct current power source.

49. The method as defined by claim 1 wherein the substrate has an original crystal lattice structure, further wherein providing comprises chemically altering the crystal lattice structure of the substrate to have a new crystal lattice structure, the new crystal lattice structure being more break resistant than the original crystal lattice structure.
